(19) United States
(12) Patent Application Publication
(10) Pub. No.: US 2015/0351225 A1
(43) Pub. Date: Dec. 3, 2015

(54) METAL-BASED MOUNTING BOARD AND METHOD OF MANUFACTURING METAL-BASED MOUNTING BOARD

(71) Applicant: SUMITOMO BAKELITE CO., LTD., Tokyo (JP)

(72) Inventors: Yoshihide Nii, Anjo-shi (JP); Toshio Komiyatani, Tokyo (JP); Yukiharu Yuzuriha, Tokyo (JP)

(73) Assignee: SUMITOMO BAKELITE CO., LTD., Tokyo (JP)

(21) Appl. No.: 14/728,150

(22) Filed: Jun. 2, 2015

(30) Foreign Application Priority Data
Jun. 3, 2014 (JP) 2014-115046

(51) Int. Cl. H05K 1/02; H05K 1/18; H05K 3/40; H05K 1/11

(52) U.S. Cl. CPC H05K 1/0209; H05K 1/115; H05K 1/181; H05K 3/4084

(57) ABSTRACT

A metal-based mounting board according to the present invention includes: a metal-based circuit board including a metal substrate through which a through-hole is provided along a thickness direction thereof, an insulating film provided on the metal substrate and a metal film provided on the insulating film, wherein the through-hole opens on a surface of the metal film on the opposite side of the metal substrate via the insulating film and the metal film; an electronic component connected to the metal film, the electronic component including an electronic component main body and a conductive leg portion electrically connected to the electronic component main body and inserted into the through-hole; and an insulating portion provided at least between the leg portion locating inside the through-hole and the metal substrate, and having a function of preventing them from making contact with each other.

### CROSS-REFERENCE TO RELATED APPLICATION

This application is based on and claims a priority from a Japanese Patent Application No. 2014-115046 filed on Jun. 3, 2014, which is hereby expressly incorporated by reference herein in its entirety.

### BACKGROUND OF THE INVENTION

1. Field of the Invention

The present invention relates to a metal-based mounting board and a method of manufacturing a metal-based mounting board.

2. Description of the Related Art

Conventionally, inverter devices or power semiconductor devices each of which is formed by mounting semiconductor elements such as an insulated gate bipolar transistor (IGBT) and a diode, and electronic components such as a resistance and a condenser on a circuit board are known.

Since such devices include electronic components each having a large amount of heat generation, they are required to exhibit high heat radiation. In order to secure such high heat radiation, devices each having a structure in which a metal plate layer (a metal substrate) is bonded to an insulating resin adhesive layer (an insulating film) are being developed (see Patent document 1).

However, there is a problem in that since such devices have large heat fluctuation, it is impossible to make connection reliability of the electronic component to the circuit board sufficiently high.

Patent Document 1: JP-A 2011-216619

### SUMMARY OF THE INVENTION

Accordingly, it is an object of the present invention to provide a metal-based mounting board having high reliability, and to provide a method capable of effectively manufacturing such a metal-based mounting board having high reliability.

In order to achieve such an object, the present invention includes the following features (1) to (13).

(1) A metal-based mounting board comprising:

a metal-based circuit board including a metal substrate through which a through-hole is provided along a thickness direction thereof, an insulating film provided on the metal substrate and a metal film provided on the insulating film, wherein the through-hole opens on a surface of the metal film on the opposite side of the metal substrate via the insulating film and the metal film;

an electronic component connected to the metal film, the electronic component including an electronic component main body and a conductive leg portion electrically connected to the electronic component main body and inserted into the through-hole; and

an insulating portion provided at least between the leg portion locating inside the through-hole and the metal substrate, and having a function of preventing them from making contact with each other.

(2) The metal-based mounting board according to the above feature (1), wherein a minimum width of the insulating portion existing between the metal substrate and the leg portion in the range of 10 μm to 5 mm.

(3) The metal-based mounting board according to the above feature (1) or (2), wherein a thickness of the metal substrate is in the range of 0.3 to 7.0 mm.

(4) The metal-based mounting board according to any one of the above features (1) to (3), wherein in the case where a thickness of the metal substrate is defined as T₀ [mm] and a length of the leg portion locating inside the through-hole is defined as T₁ [mm], T₀ and T₁ satisfy a relationship of T₁/T₀≧0.5.

(5) The metal-based mounting board according to any one of the above features (1) to (4) further comprising a metal piece provided inside the through-hole via the insulating portion, the metal piece making contact with the leg portion.

(6) The metal-based mounting board according to the above feature (5), wherein in the case where a thickness of the metal substrate is defined as T₀ [mm] and a thickness of the metal piece is defined as T₂ [mm], T₀ and T₂ satisfy a relationship of 0.5≦T₂/T₀≦1.5.

(7) The metal-based mounting board according to any one of the above features (1) to (6), wherein a thickness of the metal film is in the range of 10 to 500 μm.

(8) The metal-based mounting board according to any one of the above features (1) to (7), wherein the leg portion has a male screw part, and

wherein the metal-based mounting board further includes a portion having a female screw part, and having a function of fixing the leg portion to the metal-based circuit board by being screwed to the male screw part in a state that the leg portion is inserted into the through-hole.

(9) The metal-based mounting board according to any one of the above features (1) to (8), wherein the electronic component is connected to the metal film of the metal-based circuit board without a connector.

(10) The metal-based mounting board according to any one of the above features (1) to (9), wherein the electronic component further includes a portion having a cable through which the electronic component main body and the leg portion are connected to each other.

(11) The metal-based mounting board according to any one of the above features (1) to (10), wherein the leg portion is electrically connected to the metal film.

(12) A method of manufacturing a metal-based mounting board comprising:

preparing a metal-based circuit board including a metal substrate through which a through-hole is provided along a thickness direction thereof, an insulating film provided on the metal substrate and a metal film provided on the insulating film, wherein the through-hole opens on a surface of the metal film on the opposite side of the metal substrate via the insulating film and the metal film; and

fixing a conductive leg portion of an electronic component to the metal substrate by inserting the leg portion into the through-hole via an opening of the metal film, and then providing an insulating portion at least between the leg portion locating inside the through-hole and the metal substrate such that they do not make contact with each other.

(13) The method of manufacturing a metal-based mounting board according to the above feature (12), wherein the metal-based circuit board is obtained by forming the through-hole through a laminated body including the metal substrate, the insulating film and the metal film.

### Effect of the Invention

According to the present invention, it is possible to provide a metal-based mounting board having high reliability, and to provide a method capable of effectively manufacturing such a metal-based mounting board having high reliability.

### BRIEF DESCRIPTION OF THE DRAWINGS

FIG. 1 is a vertical cross-sectional view schematically showing a first embodiment of a metal-based mounting board according to the present invention.

FIG. 2A is a vertical cross-sectional view schematically showing a second embodiment of the metal-based mounting board according to the present invention.

FIG. 2B is a horizontal cross-sectional view schematically showing the second embodiment of the metal-based mounting board according to the present invention (a sectional view taken along line A-A of FIG. 1).

FIG. 3 is a vertical cross-sectional view schematically showing a conventional metal-based mounting board.

Each of FIG. 4A to FIG. 4D is a vertical cross-sectional view schematically showing a preferred embodiment of a method of manufacturing a metal-based mounting board according to the present invention.

Each of FIG. 5A to FIG. 5C is a vertical cross-sectional view schematically showing the preferred embodiment of the method of manufacturing the metal-based mounting board according to the present invention.

### DETAILED DESCRIPTION OF THE INVENTION

Hereinbelow, description will be made on a metal-based mounting board and a method of manufacturing a metal-based mounting board according to the present invention in detail based on preferred embodiments shown in the attached drawings.

### Metal-Based Mounting Board

First, the metal-based mounting board according to the present invention will be described.

### First Embodiment

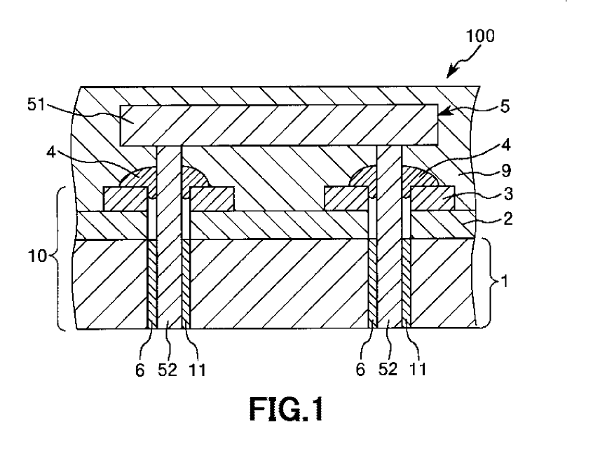

FIG. 1 is a vertical cross-sectional view schematically showing a first embodiment of the metal-based mounting board according to the present invention.

In this regard, in the following description, the upper side in FIG. 1 is referred to as the “upper”, the lower side therein is referred to as the “lower”, the right side therein is referred to as the “right”, and the left side therein is referred to as the “left”. Further, the drawings referred in this specification exaggeratingly show a part of components, and do not correctly reflect an actual size ratio and the like thereof.

A metal-based mounting board (an electronic device) 100 includes a metal-based circuit board 10, and an electronic component 5 provided on the metal-based circuit board 10.

### Metal-Based Circuit Board

The metal-based circuit board 10 includes a metal substrate 1, an insulating film 2 provided on the metal substrate 1, and a metal film 3 provided on the insulating film 2.

### Metal Substrate

The metal substrate 1 has a function of supporting the insulating film 2 and the metal film 3.

The metal substrate 1 is constituted from a material containing a metal material. The metal material generally has excellent heat transfer. Therefore, the metal-based circuit board 10 including such a metal substrate 1 can exhibit superior heat radiation as a whole.

Examples of the metal material constituting the metal substrate 1 include, but are not especially limited to, metal simple substances such as aluminum and copper, alloys each containing at least one type selected therefrom, and the like. Among them, aluminum or an aluminum alloy is preferable as the metal material from a comprehensive viewpoint based on excellent heat transfer (heat radiation), mechanical strength, chemical stability, a balance of a linear expansion coefficient and heat transfer, and the like.

A thickness of the metal substrate 1 is not limited to a specific value, but is preferably in the range of 0.3 to 7.0 mm, and more preferably in the range of 0.5 to 5.0 mm.

If the thickness of the metal substrate 1 is a value falling within the above range, it is possible to make properties such as the heat radiation and the mechanical strength of the metal substrate 1 especially excellent, and to especially improve workability such as a bending property of the metal substrate 1.

In contrast, if the thickness of the metal substrate 1 is less than the above lower limit value, a falling tendency in the heat radiation and the mechanical strength of the metal substrate 1 occurs.

On the other hand, if the thickness of the metal substrate 1 exceeds the above upper limit value, a falling tendency in the workability such as the bending property of the metal substrate 1 occurs.

A plurality of through-holes 11 are provided so as to pass through the metal substrate 1 along a thickness direction thereof. In this specification, a portion of the metal substrate 1 where the through-holes 11 are not provided is occasionally referred to as a “real portion 12”.

A width of each through-hole 11 (a diameter of each through-hole 11 in the case where a shape of each through-hole 11 in a planar view thereof is a circular shape) is not limited to a specific value, but is preferably in the range of 0.3 to 10 mm, and more preferably in the range of 0.5 to 5.0 mm.

If the width of each through-hole 11 is a value falling within the above range, it is possible to make mechanical strength and heat transfer of the metal-based circuit board 10 sufficiently excellent, and to more reliably prevent problems such as short circuit and leak between the metal substrate 1 and the electronic component 5 (each of leg portions 52 which will be described below) from occurring. This makes it possible to especially improve reliability of the metal-based mounting board 100.

Further, it is possible to easily perform alignment between each through-hole 11 and a corresponding leg portion 52 during manufacture of the metal-based mounting board 100. This makes it possible to make productivity of the metal-based mounting board 100 especially superior.

### Insulating Film

The insulating film 2 is a film having an insulating property, and has functions of preventing a short circuit between a circuit formed within the metal film 3 and the metal substrate 1 and bonding the metal film 3 to the metal substrate 1.

A thickness of the insulating film 2 is not limited to a specific value, but is preferably in the range of 40 to 300 μm.

If the thickness of the insulating film 2 is a value falling within the above range, it is possible for the insulating film 2 to effectively transfer the heat applied from the upper side thereof to the metal substrate 1. This makes it possible to make the heat radiation of the metal-based circuit board 10 as a whole especially excellent, and to effectively absorb generation of heat stress due to a difference between thermal expansion coefficients of the metal substrate 1 and the insulating film 2. Further, it is also possible to make the insulating property of the insulating film 2 specifically excellent.

In contrast, if the thickness of the insulating film 2 is less than the above lower limit value, there is a possibility that it becomes difficult to sufficiently absorb the generation of the heat stress between the metal substrate 1 and the insulating film 2 depending on the difference between the thermal expansion coefficients of the metal substrate 1 and the insulating film 2. Further, there is a possibility that it becomes difficult to make the insulating property of the insulating film 2 sufficiently excellent.

Further, if the thickness of the insulating film 2 exceeds the above upper limit value, a falling tendency in the heat radiation of the metal-based circuit board 10 as a whole occurs.

The insulating film 2 has only to have the insulating property as a whole, but is generally constituted from an insulating material having a high insulating property.

Examples of the constituent material of the insulating film 2 include various kinds of insulating resin materials, various kinds of ceramics materials, and the like.

Examples of the insulating material constituting the insulating film 2 include an epoxy resin, a phenoxy resin, and the like.

As the epoxy resin, an epoxy resin having at least one of an aromatic ring structure and an alicyclic structure (an alicyclic carbon ring structure) can be appropriately used.

By using such an epoxy resin, it is possible to increase a glass transition temperature of the insulating film 2, and to further improve the heat transfer of the insulating film 2.

Examples of the epoxy resin having the aromatic ring structure or the alicyclic structure include: a bisphenol type epoxy resin such as bisphenol A type epoxy resin, bisphenol F type epoxy resin, bisphenol S type epoxy resin, bisphenol E type epoxy resin, bisphenol M type epoxy resin, bisphenol P type epoxy resin, or bisphenol Z type epoxy resin; a novolac type epoxy resin such as phenol novolac type epoxy resin, cresol novolac type epoxy resin, or tetraphenol group-ethane type novolac type epoxy resin; a biphenyl type epoxy resin; an aryl alkylene type epoxy resin such as a phenol aralkyl type epoxy resin having a biphenylene skeleton; a naphthalene type epoxy resin; and the like. In this regard, one type of them can be used alone, or two or more of them can be used in combination as such an epoxy resin.

In the case where the insulating film 2 is constituted from a material containing the phenoxy resin, it is possible to improve bending resistant of the insulating film 2.

Further, by containing the phenoxy resin, it becomes possible to decrease an elastic modulus of the insulating film 2. This makes it possible to improve a stress relief force of the metal-based circuit board 10.

Examples of the phenoxy resin include a phenoxy resin having a bisphenol skeleton, a phenoxy resin having a naphthalene skeleton, a phenoxy resin having an anthracene skeleton, a phenoxy resin having a biphenyl skeleton, and the like. Further, a phenoxy resin having a plurality of types of these skeletons can also be used.

Examples of the ceramics material constituting the insulating film 2 include alumina and the like.

The insulating film 2 may include the ceramics material and the insulating resin material. For example, the insulating film 2 may be constituted from a material in which particles each composed of the ceramics material are dispersed in the insulating resin material.

The insulating film 2 may have an uniform composition at various regions thereof, or different compositions at a part of the regions. For example, the insulating film 2 may be a laminated body having a plurality of layers with different compositions, or may be constituted from a material of which a composition changes along the thickness direction thereof in an inclined manner.

### Metal Film

The metal film 3 is a portion forming a circuit of the metal-based circuit board 10.

The metal film 3 is formed of metals such as copper, aluminum, nickel, iron and tin. In this regard, the metal film 3 may contain two or more types of the metals.

A thickness of the metal film 3 is not limited to a specific value, but is preferably in the range of 10 to 500 μm, and more preferably in the range of 20 to 300 μm.

If the thickness of the metal film 3 is a value falling within the above range, it is possible to especially improve durability of the metal-based mounting board 100. Further, it is also possible to make loss of electric current in the metal film 3 smaller, to thereby more stably pass larger electric current through the metal film 3.

In this regard, additional layers such as a bonding layer may be provided between the insulating film 2 and the metal film 3.

The metal film 3 may have an uniform composition at various regions thereof, or different compositions at a part of the regions. For example, the metal film 3 may be a laminated body having a plurality of layers with different compositions, or may be constituted from a material of which a composition changes along the thickness direction thereof in an inclined manner.

In such a metal-based circuit board 10, the plurality of through-holes 11 each passing through the metal substrate 1 along the thickness direction thereof are provided (formed). Each through-hole 11 opens on an upper surface (a surface on the opposite side of the metal substrate 1) of the metal film 3 via the insulating film 2 and the metal film 3. In other words, also in the insulating film 2 and the metal film 3, provided are through-holes each passing through the insulating film 2 and the metal film 3 along a thickness direction thereof and communicating with the through-hole 11.

### Electronic Component

The electronic component 5 is connected to the metal film 3 of the above mentioned metal-based circuit board 10. In this way, an electronic circuit has been completed.

Examples of the electronic component 5 include: an IC chip such as a microcomputer; a semiconductor element such as an insulated gate bipolar transistor or a diode; a resistance; a condenser; and the like.

The electronic component 5 includes an electronic component main body 51 and a plurality of conductive leg portions 52 each electrically connected to the electronic component main body 51. As shown in FIG. 1, in this embodiment, the leg portions 52 are provided so as to protrude downward from the electronic component main body 51.

Each leg portion 52 is inserted into the corresponding through-hole 11 of the metal substrate 1. Further, an insulating portion 6 is provided around each leg portion 52, that is, between each leg portion locating inside the through-hole 11 and the metal substrate 1 (the real portion 12).

In this way, in the metal-based mounting board 100, the electronic component 5 is not fixed on a surface of the metal-based circuit board 10 by a brazing material such as a solder, but is fixed to the metal substrate 1 (the metal-based circuit board 10) by inserting a part thereof (each leg portion 52) into the corresponding through-hole 11 provided in the metal substrate 1 via an opening of the metal film 3, and then providing the insulating portion 6 around each leg portion 52.

Therefore, involuntary positional displacement of the electronic component 5 to the metal-based circuit board 10 can be prevented, and thus a bonding strength and bonding reliability of the electronic component 5 to the metal-based circuit board 10 becomes excellent. Further, since contact between each leg portion 52 and the metal substrate 1 is blocked by the insulating portion 6, the short circuit, the leak and the like of each leg portion 52 (the electronic component 5) and the metal substrate 1 are reliably prevented.

For the above reasons, the metal-based mounting board 100 has excellent reliability. Further, the metal-based mounting board 100 in which the leg portions 52 of the electronic component 5 are inserted into the through-holes 11 provided in the metal substrate 1 has smaller loss of electric current than a metal-based mounting board in which the electronic component is fixed on the surface of the metal-based circuit board, and thus it is easy to extract larger electric current therefrom.

At least a part of each leg portion 52 in a longitudinal direction thereof has only to be inserted into the through-hole 11. However, in the case where the thickness of the metal substrate 1 is defined as T₀ [mm] and a length of each leg portion 52 locating inside the through-hole 11 is defined as T₁ [mm], T₀ and T₁ preferably satisfy a relationship of T₁/T₀≧0.5, and more preferably satisfy a relationship of T₁/T₀≧0.8.

By satisfying such a relationship, it is possible to especially improve a fixing force of the electronic component 5 to the metal-based circuit board 10.

In this regard, a distal side portion of each leg portion 52 is located inside the through-hole 11 without penetrating through the through-hole 11 in the configuration shown in FIG. 1, but a distal end of each leg portion 52 may be exposed outside the through-hole 11 (at the lower side in FIG. 1) with penetrating through the through-hole 11.

For example, examples of a constituent material of each leg portion 52 include the material described as the constituent material of the metal film 3, and the like. In this regard, the constituent material of each leg portion 52 and the constituent material of the metal film 3 may be the same as each other or may be different from each other.

### Insulating Portion

The insulating portion 6 is provided at least between the leg portion 52 and the metal substrate 1 inside each through-hole 11. In this way, the insulating portion 6 exhibits a function of blocking the contact between each leg portion 52 (the electronic component 5) and the metal substrate 1 and a function of fixing each leg portion 52 (the electronic component 5) to the metal-based circuit board 10 (the metal substrate 1).

By providing such an insulating portion 6, it is possible to keep a distance between each leg portion 52 and the metal substrate 1 (the real portion 12), to thereby surely block the contact therebetween. This makes it possible to reliably prevent the short circuit and the leak between each leg portion 52 (the electronic component 5) and the metal substrate 1 from being generated.

Further, by providing the insulating portion 6, each leg portion 52 (the electronic component 5) can be also appropriately fixed to the metal-based circuit board 10, to thereby prevent the involuntary positional displacement of the electronic component 5 to the metal-based circuit board 10. As a result, the bonding strength and the bonding reliability of the electronic component 5 to the metal-based circuit board 10 becomes excellent.

The insulating portion 6 has only to exhibit the above mentioned functions. Therefore, inside each through-hole 11, the insulating portion 6 may be provided in a whole space between the leg portion 52 and the metal substrate 1 (the real portion 12), or may be provided in only a part of the space.

For example, the insulating portion 6 may be selectively provided in only a part of the space along a height direction (a longitudinal direction) thereof, or may be in only a part of the space along a circumferential direction of each leg portion 52. In the latter case, the insulating portion 6 is preferably formed from a plurality of small insulating portions separately provided along the circumferential direction of each leg portion 52 at roughly regular intervals.

### Brazing Material

The metal film 3 and each leg portion 52 (the electronic component 5) are bonded (brazed) together by a brazing material 4. In this way, each leg portion 52 is electrically connected to the metal film 3 via the brazing material 4.

In this way, by performing the fixation of each leg portion 52 to the metal substrate 1 (the metal-based circuit board 10) by the insulating portion 6 and the fixation of each leg portion 52 to the metal film 3 (the metal-based circuit board 10) by the brazing material 4, the fixing force of the electronic component 5 to the metal-based circuit board 10 becomes especially excellent.

For example, as the brazing material 4, a solder, a silver solder, a copper solder, a phosphorus copper solder, a brass solder, an aluminum solder, a nickel solder and the like can be used.

A minimum width of the insulating portion 6 existing between the metal substrate 1 (the real portion 12) and each leg portion 52 (a minimum distance between the real portion 12 and each leg portion 52) is preferably in the range of 10 μm to 5 mm, and more preferably in the range of 100 to 500 μm.

If the minimum width of the insulating portion 6 existing between the real portion 12 and each leg portion 52 is a value falling the above range, the effects obtained by providing the insulating portions 6 as described above exhibit more remarkably.

In this regard, the insulating portion 6 is selectively provided inside each through-hole 11 in the configuration shown in FIG. 1, but may be provided at the other places (e.g., a lower surface of the metal substrate 1, an inside of each through-hole provided in the insulating film 2, an inside of each through-hole provided in the metal film 3, the upper surface of the metal film 3 and the like) in addition to the inside of each through-hole 11.

For example, examples of a constituent material of the insulating portion 6 include the material described as the constituent material of the insulating film 2, and the like. In this regard, the constituent material of the insulating portion 6 and the constituent material of the metal film 3 may be the same as each other or may be different from each other.

### Sealing Material

In the configuration shown in FIG. 1, a sealing material 9 is provided on the side (the upper side in FIG. 1) of a surface of the metal-based circuit board 10 on which the circuit (the metal film 3) is formed, to thereby cover the metal film 3 and the electronic component 5.

This makes it possible to make moisture resistance, chemical resistance and the like of the metal-based mounting board 100 especially excellent, to thereby improve the reliability of the metal-based mounting board 100.

The metal-based mounting board 100 may be used in any devices. Examples of such devices include semiconductor devices such as a power semiconductor device, a LED illumination and an inverter device. Although such semiconductor devices have generally large amounts of heat generation, their heat can be efficiently radiated according to the present invention. Therefore, the present invention can be appropriately used in such semiconductor devices.

Here, the inverter device is a device electrically generating an alternating current from a direct current (having a reverse changing feature). Further, the power semiconductor device has properties such as a high pressure-resistant property, a high current property and a high speed and frequency property as compared with an usual semiconductor element, and is generally called a power device. Examples of such a power semiconductor device include a rectifier diode, a power transistor, a power MOSFET, an insulated gate bipolar transistor (IGBT), a thyristor, a gate turn-off thyristor (GTO), a triac, and the like.

### Second Embodiment

Next, a second embodiment of the metal-based mounting board according to the present invention will be described.

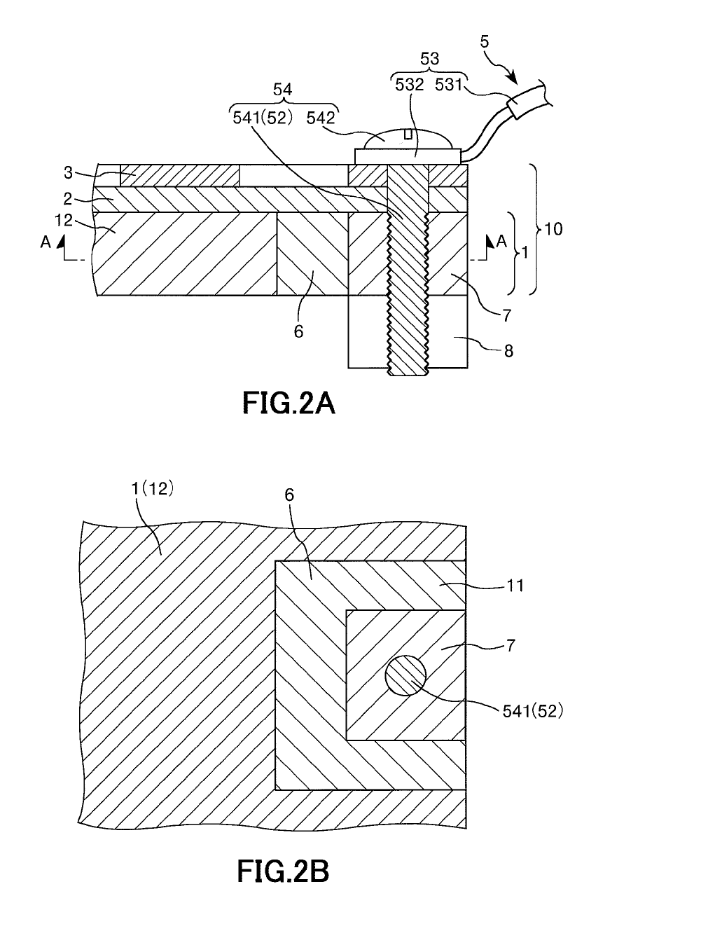

FIG. 2A is a vertical cross-sectional view schematically showing the second embodiment of the metal-based mounting board according to the present invention, FIG. 2B is a horizontal cross-sectional view schematically showing the second embodiment of the metal-based mounting board according to the present invention (a sectional view taken along line A-A of FIG. 1). Hereinafter, the second embodiment will be described with emphasis placed on points differing from the first embodiment. No description will be made on the same points.

As shown in FIG. 2B, in the metal-based mounting board 100 according to this embodiment, the through-hole 11 opens at an edge portion of the metal substrate 1. In this way, a whole circumference of the through-hole 11 need not be defined by the real portion 12.

Further, in this embodiment, a metal piece 7 is provided inside the through-hole 11, and this metal piece 7 makes contact with (is screwed to) the leg portion 52. Further, the insulating portion 6 is provided around the metal piece 7. In this way, the insulating portion 6 has only to have the function of blocking the contact between the leg portion 52 of the electronic component 5 and the real portion 12, and therefore it may not directly make contact with the leg portion 52.

As described above, by providing such a metal piece 7, it is possible to especially improve the fixing force of the electronic component 5 to the metal-based circuit board 10. Further, it is also possible to make the heat transfer of the metal-based mounting board 100 as a whole further excellent.

Examples of a metal material constituting the metal piece 7 include, but are not especially limited to, metal simple substances such as aluminum and copper, alloys each containing at least one type selected therefrom, and the like.

A thickness of the metal piece 7 is not a specific value, but is preferably in the range of 0.3 to 7 mm, and more preferably in the range of 0.5 to 5 mm.

If the thickness of the metal piece 7 is a value falling within the above range, it is possible to prevent the metal-based mounting board 100 from thickening, and to make the heat radiation and the mechanical strength thereof especially excellent.

In the case where the thickness of the metal substrate 1 is defined as T₀ [mm] and the thickness of the metal piece 7 is defined as T₂ [mm], T₀ and T₂ preferably satisfy a relationship of 0.5≦T₂/T₀≦1.5, and more preferably satisfy a relationship of 0.8≦T₂/T₀≦1.2.

By satisfying such a relationship, it is possible to more effectively prevent the metal-based mounting board 100 from thickening, and to make the heat radiation and the mechanical strength thereof further excellent.

The metal piece 7 is provided as an additional member between the leg portion 52 and the insulating portion 6 in the configuration shown in FIGS. 2A and 2B, but, likewise, an additional member may be provided between the real portion 12 and the insulating portion 6.

Further, in the configuration shown in FIG. 2A, the electronic component 5 includes a connection wiring portion (a portion having a cable) 53 connecting to the electronic component main body 51 (not indicated in FIG. 2A), and a bolt (a portion having a female screw part) 54 connecting to the connection wiring portion 53. In this way, the electronic component 5 may include a plurality of portions existing in a state of separating from each other before manufacturing the metal-based mounting board 100.

The connection wiring portion 53 has a connection wiring (the cable) 531, and a ring-shaped wiring terminal 532 provided at an end of the connection wiring 531 on the opposite side of the electronic component main unit 51. Further, the bolt 54 includes a shank 541 having the male screw part, and a head 542 provided on one end of the shank 541. The shank 541 of the bolt 54 is penetrated through an inside of the wiring terminal 532, and then inserted into the through-hole 11 provided in the metal substrate 1 via the opening of the metal film 3.

Then, by holing the wiring terminal 532 by the head 542 of the bolt 54 and the metal film 3, the electronic component 5 is connected to the metal-based circuit board 10. Further, in this state, the bolt 54 is electrically connected to the metal film 3 directly or via the wiring terminal 532. In this regard, in this embodiment, the shank 541 (the portion having the male screw part) of the bolt 54 serves as the leg portion 52.

Further, in the configuration shown in FIG. 2A, the shank 541 (the bolt 54) of the electronic component 5 is penetrated through the through-hole 11, and a nut (a portion having a female screw part) 8 is screwed to a portion of the bolt 54 protruding from a lower surface of the metal piece 7. In this way, the bolt 54 (the electronic component 5) is fixed to the metal-based circuit board 10.

According to such a configuration, it is possible to more improve the fixing force of the electronic component 5 to the metal-based circuit board 10. Further, in the case where the wiring terminal 532 is deformed so as to have a wave shape, the wiring terminal 532 can serve as a wave washer. This makes it possible to further improve the fixing force of the electronic component 5 to the metal-based circuit board 10, and to prevent looseness of the bolt 54 from being caused.

The nut 8 may be formed of any materials, but is preferably formed of a metal material. This makes it possible to more stably and firmly fix the electronic component 5 to the metal-based circuit board 10. Further, this also makes it possible to make the heat transfer of the metal-based mounting board 100 as a whole further excellent.

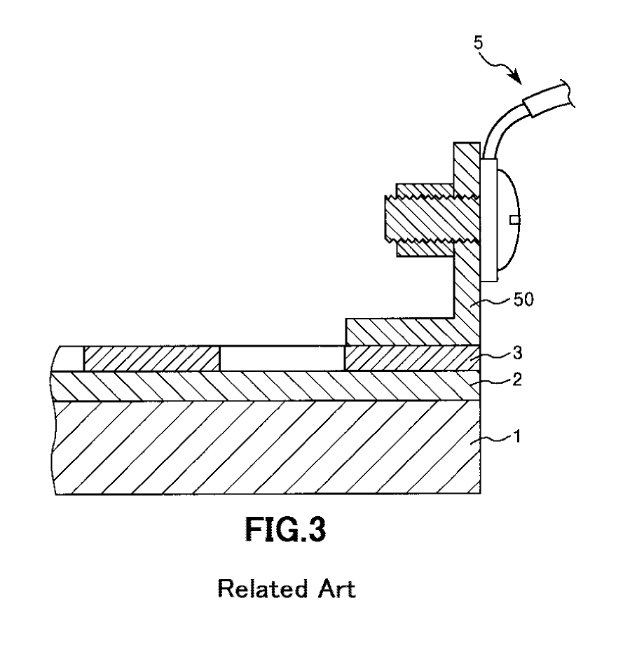

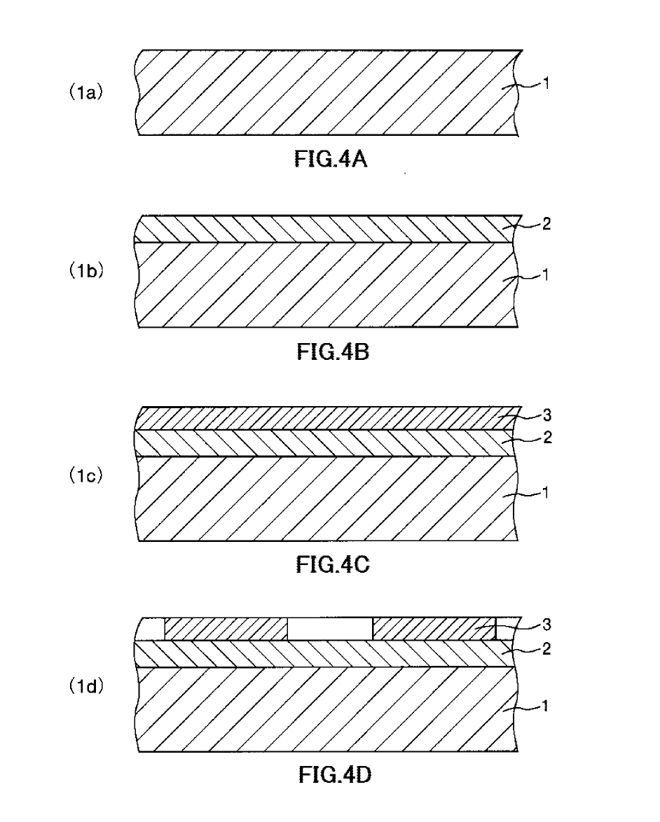

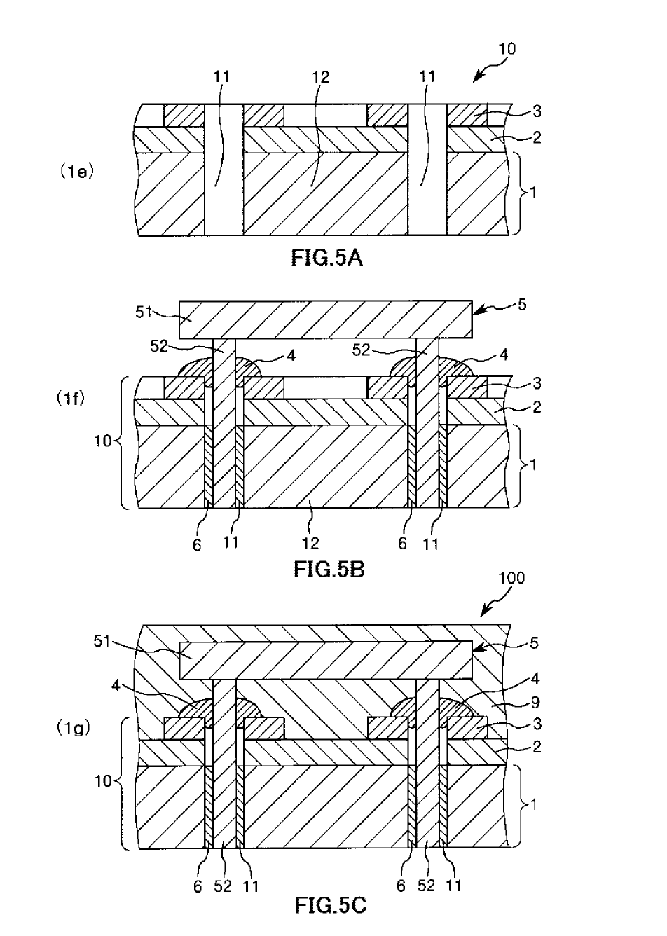

Further, in the past, as shown in FIG. 3, in the case of fixing the electronic component 5 having the cable, the cable was fixed to a L-shaped connector 50 bonded on the metal film 3 by a solder with screw clamp. In this case, the screw clamp of the cable was performed from a horizontal direction (a crosswise direction in FIG. 3) of the metal substrate 1. However, the screw clamp to be performed from such a direction has poor workability due to existence of the other electronic components and the like. Further, defects or the like of the other electronic components often occurred by making contact with a driver during the screw clamp.

On the other hand, in this embodiment, the operation of tightening up the bolt 54 can be performed from a direction perpendicular to the surface of the metal substrate 1 (a normal direction thereof). Therefore, the occurrence of the problem as described above is effectively prevented. Further, since the connector 50 need not be bonded on the metal film 3, the present invention also has an advantage in decreasing the production cost of the metal-based mounting board 100.

Further, in the configuration shown in FIG. 2A, a female screw part is also provided in the metal piece 7.

This makes it possible to further improve the fixing force of the electronic component 5 to the metal-based circuit board 10. Further, in this case, since the metal piece 7 serves as the portion having the male screw part capable of being screwed to the male screw part of the shank 541, the nut 8 may be omitted.

### Method of Manufacturing Metal-Based Mounting Board

Next, a method of manufacturing a metal-based mounting board will be described.

Each of FIG. 4A to FIG. 4D and FIG. 5A to FIG. 5C is a vertical cross-sectional view schematically showing a preferred embodiment of a method of manufacturing a metal-based mounting board according to the present invention.

As shown in FIG. 4A to FIG. 4D and FIG. 5A to FIG. 5C, the method of manufacturing the metal-based mounting board according to this embodiment has a step of preparing the metal-based circuit board 10 including the metal substrate 1 through which the through-holes 11 are provided along the thickness direction thereof, the insulating film 2 provided on the metal substrate 1 and the metal film 3 provided on the insulating film 2, wherein the through-holes 11 open on the upper surface (the surface on the opposite side of the metal substrate 1) of the metal film 3 via the insulating film 2 and the metal film 3 (including sub-steps 1a to 1e); a step (1f) of fixing each leg portion 52 of the electronic component 5 to the metal substrate 1 by inserting each leg portion 52 into the corresponding through-hole 11 via the opening of the metal film 3, and then providing the insulating portion 6 between each leg portion 52 locating inside the through-hole 11 and the metal substrate 1 such that they do not make contact with each other, and fixing each leg portion 52 to the metal film 3 by the brazing material 4; and a step (1g) of sealing the metal film 3 and the electronic component 5 by the sealing material 9.

In the step of preparing the metal-based circuit board 10, first, as shown in FIG. 4A, the metal substrate 1 is prepared (the sub-step 1a).

Thereafter, as shown in FIG. 4B, the insulating film 2 is formed on the metal substrate 1 (the sub-step 1b).

The formation of the insulating film 2 can be formed by providing a resin layer in a B stage state which constituted from a composition for forming the insulating film 2 on the metal substrate 1. In this case, the resin layer may be formed on the metal substrate 1 by applying the composition onto the metal substrate 1, or the resin layer may be formed on the metal substrate 1 by producing a carrier material with resin layer in which the resin layer is formed on a carrier material, and then laminating the carrier material with resin layer onto the metal substrate 1.

In this regard, a thickness of the resin layer in the B stage state is preferably in the range of 40 to 300 μm.

Hereinbelow, description will be made on a method of producing the carrier material with resin layer, and then laminating this carrier material with resin layer onto the metal substrate 1.

First, the resin layer is formed on the carrier material, to obtain the carrier material with resin layer.

As the carrier material, for example, a resin film such as a polyethylene terephthalate film or a metal foil such as a copper foil can be used.

In this regard, a thickness of the carrier material is preferably in the range of 10 to 500 μm.

Next, the carrier material with resin layer is laminated onto the metal substrate 1 such that a surface of the carrier material with resin layer on the side of the resin layer makes contact with a surface of the metal substrate 1. Thereafter, the resin layer is cured by being pressed and heated, to thereby form the insulating film 2.

Next, as shown in FIG. 4C, the metal film 3 is formed on a surface of the insulating layer 2 (the sub-step 1c).

The formation of the metal film can be performed onto the surface of the insulating film 2 exposed by removing the carrier material from the insulating film 2. In this regard, in the case where the carrier material is the metal foil, the carrier material may be directly used as the metal film 3.

Next, as shown in FIG. 4D, a circuit is formed by processing the metal film 3 in a predetermined pattern with etching or the like (the sub-step 1d). In this way, a laminated body including the metal substrate 1, the insulating film 2 and the metal film 3 is obtained.

In the case where a multi-layered circuit is produced, after the circuit is formed, an insulating film and a metal foil (a metal sheet) are further laminated onto the circuit sequentially, and then the metal foil is processed with etching or the like in the same manner as described above, to thereby form a circuit. In this way, it is possible to obtain a laminated body including the multi-layered circuit. In this regard, it is preferred that the insulating film is formed of the same composition as the composition used for forming the above mentioned insulating film 2 from the viewpoint of further improving the heat transfer of the finally obtained metal-based mounting board 100.

Thereafter, as shown in FIG. 5A, through-holes each continuously passing through the metal substrate 1, the insulating film 2 and the metal film 3 along the thickness direction thereof are formed in the obtained laminated body (the sub-step 1e). That is, through-holes 11 each opening on the upper surface of the metal film 3 via the insulating film 2 and the metal film 3 are formed in the metal substrate 1. In this way, a metal-based circuit board 10 is obtained.

By forming the through-holes (including the through-holes 11) in the laminated body including the metal substrate 1, the insulating film 2 and the metal film 3 in this way, it is possible to effectively prevent involuntary adhesion of the constituent material of the metal film 3 or the like on inner peripheral surfaces of the metal-based circuit board 10 defining the through-holes or the like.

Examples of a method of forming the through-holes include a machine process using a drill or the like, a laser process, an etching process, and the like.

Next, as shown in FIG. 5B, each leg portion 52 of the electronic component 5 is inserted into the corresponding through-hole 11 via the opening of the metal film 3, and then the insulating portion 6 is provided between each leg portion 52 locating inside the through-hole 11 and the metal substrate 1 (around each leg portion 52 inside the through-hole 11) such that they do not make contact with each other. In this way, each leg portion 52 is fixed to the metal substrate 1 (the step 1f).

In the step of fixing the electronic component 5 to the metal-based circuit board 10, each leg portion 52 may be inserted into the through-hole 11 after a material for forming the insulating portion 6 is applied inside the through-hole 11, or the material for forming the insulating portion 6 may be applied inside the through-hole 11 (a space between the real portion 12 and each leg portion 52) after each leg portion 52 is inserted into the through-hole 11.

Further, in this embodiment, when the electronic component 5 is fixed to the metal-based circuit board 10, the fixation of each leg portion 52 to the metal substrate 1 by the insulating portion 6 and the fixation of each leg portion 52 to the metal film 3 by the brazing material are performed.

In this way, the fixing force of the electronic component 5 to the metal-based circuit board 10 becomes especially excellent.

Thereafter, as shown in FIG. 5C, the sealing material 9 is applied on the side of a surface of the metal-based circuit board 10 on which the circuit (the metal film 3) is formed (the upper side in FIG. 5C), to thereby seal the metal film 3 and the electronic component 5 (the step 1g). In this way, the metal-based mounting board 100 according to this embodiment is obtained.

As described above, by sealing the metal film 3 and the electronic component 5 with the sealing material 9, it is possible to make the moisture resistance, the chemical resistance and the like of the metal-based mounting board 100 especially excellent, to thereby improve the reliability of the metal-based mounting board 100.

Hereinabove the preferred embodiments of the present invention have been described, but the present invention is not limited thereto. The present invention includes modification, improvement and the like within the scope capable of achieving the purposes of the present invention.

For example, arbitrary configurations of the first and second embodiments may be combined with each other. Specifically, a male screw part may be provided at a lower portion of each leg portion 52 of the first embodiment, and each leg portion 52 may be fixed to the metal substrate 1 by using a nut in addition to the insulating portion 6.

For example, a size and a shape of each through-hole 11 are constant along the thickness direction of the metal substrate 1 in the above embodiments, but may change along the thickness direction thereof. For example, each through-hole 11 may have a horizontal cross-section changing portion of which a horizontal cross-sectional area (a size of a cross-section along a planar direction) changes along the thickness direction of the metal substrate 1 in a continuous manner or a stepwise manner. This makes it possible to further improve the fixing force of the electronic component 5 to the metal-based circuit board 10.

Further, the method of manufacturing the metal-based mounting board according to the present invention has only to include the step of preparing the metal-based circuit board 10, and the step of fixing the electronic component 5 to the metal-based circuit board 10, and thus may have no step of sealing the metal film 3 and the electronic component 5 with the sealing material 9 as described above.

Furthermore, the method of manufacturing the metal-based mounting board according to the present invention may have the other steps (a pre-treatment step, an intermediate treatment step, a post-treatment step) in addition to the above mentioned steps.

Furthermore, in the method of manufacturing the metal-based mounting board according to the present invention, the insulating film 2 and the metal film 3 are sequentially formed on the metal substrate 1 to obtain the laminated body, and then the through-holes are formed in the laminated body in the above mentioned embodiment, but the insulating film 2 and the metal film 3 may be sequentially formed on a metal substrate 1 in which the through-holes 11 have been provided in advance.

Furthermore, through-holes (including the through-holes 11) may be formed in the metal substrate 1, on which the insulating film 2 has been formed, along the thickness direction thereof, and then the metal film 3 may be formed on the insulating film 2.

Furthermore, for example, in the method of manufacturing the metal-based mounting board according to the present invention, the insulating film is formed on the metal substrate 1, and then the metal film 3 is formed on the insulating film 2 in the above mentioned embodiment, but a composition for forming the insulating film 2 containing a curable resin may be applied onto the metal substrate 1 to form a coating, the metal film 3 may be formed on the coating, and then the coating (the curable resin) may be cured, to thereby obtain the insulating film 2.

Furthermore, the metal-based mounting board according to the present invention may be manufactured by using any methods, but may not be manufactured by using the above mentioned method.

Moreover, for example, the metal-based mounting board according to the present invention may have additional members such as a heat sink on the surface of the metal substrate on the opposite side of the insulating film.

What is claimed is:

1. A metal-based mounting board comprising:
a metal-based circuit board including a metal substrate through which a through-hole is provided along a thickness direction thereof, an insulating film provided on the metal substrate and a metal film provided on the insulating film, wherein the through-hole opens on a surface of the metal film on the opposite side of the metal substrate via the insulating film and the metal film;
an electronic component connected to the metal film, the electronic component including an electronic component main body and a conductive leg portion electrically connected to the electronic component main body and inserted into the through-hole; and
an insulating portion provided at least between the leg portion locating inside the through-hole and the metal substrate, and having a function of preventing them from making contact with each other.

2. The metal-based mounting board as claimed in claim 1, wherein a minimum width of the insulating portion existing between the metal substrate and the leg portion in the range of 10 μm to 5 mm.

3. The metal-based mounting board as claimed in claim 1, wherein a thickness of the metal substrate is in the range of 0.3 to 7.0 mm.

4. The metal-based mounting board as claimed in claim 1, wherein in the case where a thickness of the metal substrate is defined as T₀ [mm] and a length of the leg portion locating inside the through-hole is defined as T₁ [mm], T₀ and T₁ satisfy a relationship of T₁/T₀≧0.5.

5. The metal-based mounting board as claimed in claim 1 further comprising a metal piece provided inside the through-hole via the insulating portion, the metal piece making contact with the leg portion.

6. The metal-based mounting board as claimed in claim 5, wherein in the case where a thickness of the metal substrate is defined as T₀ [mm] and a thickness of the metal piece is defined as T₂ [mm], T₀ and T₂ satisfy a relationship of 0.5≦T₂/T₀≦1.5.

7. The metal-based mounting board as claimed in claim 1, wherein a thickness of the metal film is in the range of 10 to 500 μm.

8. The metal-based mounting board as claimed in claim 1, wherein the leg portion has a male screw part, and
wherein the metal-based mounting board further includes a portion having a female screw part, and having a function of fixing the leg portion to the metal-based circuit board by being screwed to the male screw part in a state that the leg portion is inserted into the through-hole.

9. The metal-based mounting board as claimed in claim 1, wherein the electronic component is connected to the metal film of the metal-based circuit board without a connector.

10. The metal-based mounting board as claimed in claim 1, wherein the electronic component further includes a portion having a cable through which the electronic component main body and the leg portion are connected to each other.

11. The metal-based mounting board as claimed in claim 1, wherein the leg portion is electrically connected to the metal film.

12. A method of manufacturing a metal-based mounting board comprising:
preparing a metal-based circuit board including a metal substrate through which a through-hole is provided along a thickness direction thereof, an insulating film provided on the metal substrate and a metal film provided on the insulating film, wherein the through-hole opens on a surface of the metal film on the opposite side of the metal substrate via the insulating film and the metal film; and
fixing a conductive leg portion of an electronic component to the metal substrate by inserting the leg portion into the through-hole via an opening of the metal film, and then providing an insulating portion at least between the leg portion locating inside the through-hole and the metal substrate such that they do not make contact with each other.

13. The method of manufacturing a metal-based mounting board as claimed in claim 12, wherein the metal-based circuit board is obtained by forming the through-hole through a laminated body including the metal substrate, the insulating film and the metal film.
